(19) United States
(12) Patent Application Publication
(10) Pub. No.: US 2017/0101315 A1
(43) Pub. Date: Apr. 13, 2017

(54) APPARATUS AND METHODS FOR ELECTRONIC MONITORING OF OZONE GENERATORS

(71) Applicant: SEEwater, INC., San Jacinto, CA (US)

(72) Inventor: Franklin J. Cathell, Tucson, AZ (US)

(21) Appl. No.: 14/880,022

(22) Filed: Oct. 9, 2015

(51) Int. Cl. C01B 13/11; G01R 31/02

(52) U.S. Cl. CPC C01B 13/115; G01R 31/02; C01B 2201/12; C01B 2201/90

(57) ABSTRACT

Apparatus and methods for electronic monitoring of ozone generators are provided herein. In certain configurations, an ozone generator includes ozone generation circuitry for producing ozone and a control circuit that monitors the ozone generation circuitry to determine whether or not ozone is being properly produced. The control circuit includes an AC input that receives power from an AC power supply and one or more AC outputs for providing AC output voltages to the ozone generation circuitry. The control circuit further includes one or more AC current sensors used to monitor a status of ozone production by monitoring AC current flowing into the ozone generation circuitry via the control circuit's AC outputs. The control circuit alerts a user of the status of ozone production while avoiding a need for the user to test a treatment fluid for ozone concentration and/or manually inspect or test components of the ozone generator.

### BACKGROUND

Field

Embodiments of the invention relate to electrical systems, and in particular, to electronic monitoring of ozone generators.

Description of the Related Technology

Water treatment methods, including chemical treatment and filtering, are limited in their efficacy and efficiency. For example, filters can clog or produce harmful or undesirable microbial growth, requiring difficult and/or expensive removal and replacement procedures. Chemical treatments can introduce undesired byproducts and can be limited in their range of effective treatment. There is, therefore, a need for an ozone generator for producing reliable and affordable ozone production for treatment of water and other materials.

### SUMMARY

In one aspect, an ozone generator is provided. The ozone generator includes ozone generation circuitry and a control circuit including an AC input configured to receive an AC input voltage and one or more AC outputs configured to provide one or more AC output voltages to the ozone generation circuitry. The control circuit further includes a first AC current sensor configured to sense an AC current flowing from a first AC output of the one or more AC outputs into the ozone generation circuitry.

In another aspect, a method of electronic monitoring in an ozone generator is provided. The method includes receiving an AC input voltage as an input to a control circuit of an ozone generator, providing one or more AC output voltages from one or more AC outputs of the control circuit to ozone generation circuitry of the ozone generator, and detecting when the ozone generation circuitry is producing ozone by sensing one or more AC currents flowing from the one or more AC outputs using one or more AC current sensors.

In another aspect, an apparatus is provided. The apparatus includes a control circuit including an AC input, a first AC output, and a first AC current sensor in an electrical path between the AC input and the first AC output. The apparatus further includes a first generator plate, and a first converter module in an electrical path between the first AC output of the control circuit and the first generator plate. The first AC current sensor is configured to detect when the first converter module and the first generator plate are in resonance.

### BRIEF DESCRIPTION OF THE DRAWINGS

FIG. 1 is a schematic diagram of one example of a water treatment system.

FIG. 2 is a schematic diagram of an electrical system for an ozone generator according to one embodiment.

FIG. 3 is a schematic diagram of an electrical system for an ozone generator according to another embodiment.

FIG. 4 is a schematic diagram of a control circuit according to one embodiment.

FIG. 5 is a schematic diagram of a control circuit according to another embodiment.

FIG. 6 consists of FIGS. 6-1 and 6-2 and is a circuit diagram of a control board according to one embodiment.

FIG. 7A is a front view of one embodiment of an ozone generator with a front cover closed.

FIG. 7B is a front view of the ozone generator of FIG. 7A with the front cover open.

FIG. 8 is a perspective view of one embodiment of a generator plate.

### DETAILED DESCRIPTION OF EMBODIMENTS

The following detailed description of embodiments presents various descriptions of specific embodiments of the invention. However, the invention can be embodied in a multitude of different ways as defined and covered by the claims. In this description, reference is made to the drawings in which like reference numerals may indicate identical or functionally similar elements.

Apparatus and methods for electronic monitoring of ozone generators are provided herein. In certain configurations, an ozone generator includes ozone generation circuitry for producing ozone and a control circuit that monitors the ozone generation circuitry to determine whether or not ozone is being properly produced. The control circuit alerts a user of the status of ozone production while avoiding a need for the user to test a treatment fluid for ozone concentrations and/or manually inspect or test components of the ozone generator. The control circuit can provide notification of the functioning of the ozone generator in a variety of ways, including, for example, by controlling a visual indicator such as a light, by controlling an audio indicator such as a buzzer, and/or by sending an electronic notification.

The control circuit includes an AC input that receives power from an AC power supply and one or more AC outputs for providing AC output voltages to the ozone generation circuitry. The control circuit further includes one or more AC current sensors used to monitor a status of ozone production by monitoring AC current flowing into the ozone generation circuitry via the control circuit's AC outputs. In certain implementations, the control circuit is implemented as a control board, such as a printed circuit board (PCB) that is housed in the ozone generator.

In certain configurations, the ozone generation circuitry includes a converter module and a generator plate. Additionally, an AC output of the control circuit is electrically connected to the converter module, and an AC current sensor monitors the AC current flowing into the converter module from the control circuit's AC output. The converter module generates a high voltage AC supply for the ozone generate plate based on a resonance of an inductor-capacitor (LC) resonant circuit that includes a capacitance of the generator plate and an inductance of the converter module.

When the ozone generator is properly functioning, the LC resonant circuit is in resonance, and the power converter provides the high voltage AC supply across the generator plate to produce ozone. However, when the ozone generator is not properly functioning, such as when the generator plate cracks, the converter module has an open or short circuit, and/or when the AC power supply fails, the LC resonant circuit falls out of resonance. When the LC resonant circuit falls out of resonance, the flow of AC current from the control circuit to the converter module via the AC output can decrease to a relatively low value. Accordingly, by using the AC current sensor to monitor the current flowing into the converter module via the control circuit's AC output, the AC current sensor can determine whether or not the converter module and generator plate are in resonance and producing ozone.

The teachings herein can be used to indirectly detect ozone production of an ozone generator, thereby providing ozone detection without needing to test a treatment fluid for ozone levels and/or manually inspect or test the ozone generator's components.

The control circuit can provide notification of the functioning of an ozone generator in a variety of ways, including, for example, by controlling a visual indicator such as a light, by controlling an audio indicator such as a buzzer, and/or by sending an electronic notification. In one example, a control circuit controls a visual indicator such as a light-emitting diode that is visible from outside the ozone generator's housing to notify a user of the status of ozone production without needing to open the ozone generator. In another example, a control circuit is implemented as a PCB that includes one or more visual and/or audio indicators included thereon. In yet another example, the control circuit generates an electronic notification to a user, such as by sending an electronic message to a computer and/or a mobile device over a network.

In certain implementations, the control circuit further receives one or more input signals, including, for example, a thermostat signal from a thermostat monitoring a temperature of the ozone generation circuitry. When the control circuit determines that the input signals indicate a fault condition, the control circuit alerts a user of the fault condition and electrically decouples the AC outputs used to power the ozone generation circuitry from the AC power supply.

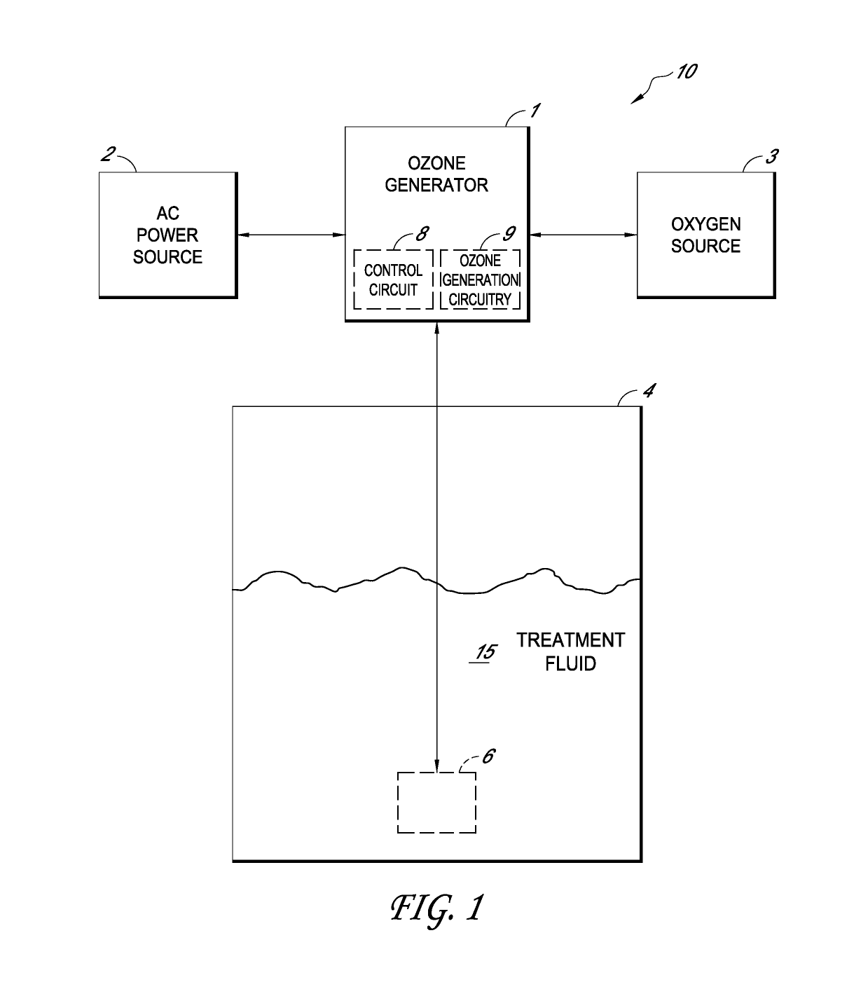

FIG. 1 is a schematic diagram of one example of a water treatment system 10. The water treatment system 10 includes an ozone generator 1, an AC power source 2, an oxygen source 3, and a reservoir 4. The ozone generator 1 includes a control circuit 8 and ozone generation circuitry 9. Additionally, the reservoir 4 includes treatment fluid 15 and a distributor 6. As shown in FIG. 1, the ozone generator 1 receives AC power from the AC power source 2 and oxygen from the oxygen source 3. As shown in FIG. 1, the ozone generator 1 and the distributor 6 are coupled to one another.

The control circuit 8 can be used to control electrical operations of the ozone generator 1 and to provide electronic monitoring. As will be described in detail herein, the control circuit 8 can include one or more AC current sensors used to determine whether or not the ozone generation circuitry 9 is properly functioning and producing ozone.

The AC power source 2 provides AC power to the control circuit 8. In certain configurations, the control circuit 8 includes an AC input that is coupled to the AC power source 2 via an electrical cable or other electrical connection. In certain configurations, the AC power source 2 corresponds to a wall outlet, such as a 120 V outlet or a 240 V outlet. However, other configurations are possible.

The oxygen source 3 can provide oxygen to the ozone generator 1 to aid the ozone generation circuitry 9 in generating ozone. In certain configurations, the oxygen source 3 can be an oxygen tank or reservoir that provides oxygen to the ozone generator 1 via a hose, pipe, or other conduit. However, other configurations are possible, such as implementations in which oxygen source 9 corresponds to air in a surrounding ambient environment.

The ozone generator 1 can be used to treat or purify the treatment fluid 15 in the reservoir 4 or other treatment site. In the illustrated configuration, the reservoir 4 includes the distributor 6, which can be coupled to the ozone generator 1 in a variety of ways, including, for example, via a hose, pipe, or other conduit. The distributor 6 can be used to distribute ozone generated by the ozone generator 1 into the treatment fluid 15.

The water treatment system 10 illustrates one application for an ozone generator. However, ozone generators can be used in a wide variety of applications, including for example, industrial, residential, and commercial applications.

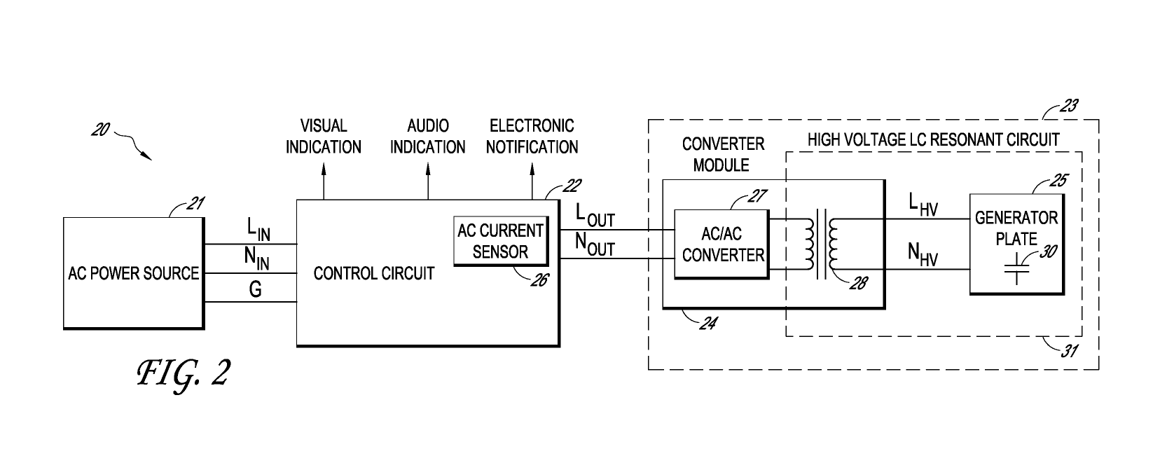

FIG. 2 is a schematic diagram of an electrical system 20 for an ozone generator according to one embodiment. The electrical system 20 includes an AC power source 21, a control circuit 22, and ozone generation circuitry 23. The ozone generation circuitry 23 includes a converter module 24 and a generator plate 25.

The control circuit 22 receives AC power from the AC power source 21. In the illustrated embodiment, the control circuit 22 includes an AC input that is coupled to the AC power source 21 by input line (L_{IN}), input neutral (N_{IN}), and input ground (G) connections. Additionally, the control circuit 22 includes an AC output that is electrically connected to the converter module 24 by output line (L_{OUT}) and output neutral (N_{OUT}) connections. The control circuit's AC output is used to provide an AC output voltage to the converter module 24.

The AC power source 21 can correspond to a wide variety of power sources. For example, the AC power source 21 can correspond to a wall outlet, such as a 120 V outlet. Although FIG. 2 illustrates an embodiment in which the AC power source 21 is electrically connected to the control circuit 22 by L_{IN}, N_{IN}, and G connections, other configurations are possible. For example, in another embodiment, the AC power source 21 is a 240 V outlet that is electrically connected to the control circuit 22 using, for instance, S-wire hot/neutral/hot connections or 4-wire hot/neutral/hot/ground connections.

The converter module 24 includes an AC/AC converter 27 and a transformer 28. The AC/AC converter 27 receives the AC output voltage from the control circuit 22, and converts the AC output voltage into an AC converted voltage having a desired frequency and magnitude. The transformer 28 includes an input that receives the AC converted voltage generated by the AC/AC converter 27 and an output that provides a high voltage AC supply on high voltage line (L_{HV}) and high voltage neutral (N_{HV}) connections. As will be described in detail further below, the high voltage AC supply is generated based on a resonance of the generator plate 25 and the converter module 24.

The high voltage AC supply has a voltage magnitude sufficient to generate ozone using the generator plate 25. In certain implementations, the high voltage AC supply can have a voltage magnitude of about 5 kV or more. The generator plate 25 can generate ozone by providing electrical discharge energy, such as corona discharge, sufficient to separate the atoms of an oxygen (O₂) source. Additionally, a portion of the separated atoms can recombine to generate ozone (O₃).

With continuing reference to FIG. 2, the generator plate 25 has a capacitance 30 that resonates with an inductance of the converter module 24, such as a self-inductance of the transformer 28. Accordingly, in the illustrated embodiment, the generator plate 25 and the transformer 28 operate as a high voltage inductor-capacitor (LC) resonant circuit 31.

In certain configurations, the capacitance 30 of the generator plate 25 resonates with a self-inductance of the transformer 28 to generate the high voltage AC supply. Thus, rather than generate the high voltage AC supply by a turns ratio of the transformer 28, the high voltage AC supply is generated based on a resonance of the generator plate 25 and the transformer 28. For instance, a quality-factor (Q-factor) of the high voltage LC resonant circuit can generate substantially all of the high voltage as opposed to the transformer's turns ratio. The AC/AC converter 27 is used to convert the AC output voltage provided by the control circuit 22 to a frequency and magnitude sufficient to drive the high voltage LC resonant circuit 31.

For instance, in one example, the AC power source 21 is a 120V/60 Hz wall outlet, which may not be of suitable frequency for resonating the high voltage LC resonant circuit 31. Thus, the AC/AC converter 27 can provide frequency conversion, including, for example, downshifting of the AC frequency to a frequency suitable for resonating the high voltage LC resonant circuit 31.

As shown in FIG. 2, the control circuit 22 includes an AC current sensor 26, which measures a flow of AC current from the AC output of the control circuit 22 to the ozone generation circuitry 23.

Since the high voltage AC supply on the L_{HV} and N_{HV} connections is generated based on a resonance of the high voltage LC resonant circuit 31, the flow of AC current from the control circuit 22 via the AC output can decrease when the high voltage LC resonant circuit 31 falls out of resonance. For example, a resonance of the high voltage LC resonant circuit 31 can be relatively narrow, and a relatively small deviation from the resonant frequency can cause a relatively large drop in the AC current. In one embodiment, the high voltage LC resonant circuit 31 has a resonant center frequency of about 13 kHz, and a half-power bandwidth of about +/−1.5 kHz.

The high voltage LC resonant circuit 31 can fall out of resonance for a variety of reasons, such as when the control circuit 22 and/or converter module 24 fails (for example, an open or short circuit), when the AC power supply 21 fails, and/or when the generator plate 25 cracks or is defective. Furthermore, in configurations including two or more generator plates, the high voltage LC resonant circuit 31 can fall out of resonance when electrical arcing undesirably occurs between the generator plate 25 and another generator plate.

Accordingly, when the high voltage LC resonant circuit 31 is out of resonance, the AC current provided to the converter module 24 via the AC output of the control circuit 22 can decrease to a relatively low value, and the AC current sensor 26 can detect a fault in ozone production. Thus the AC current sensor 26 is operable to determine whether or not the AC output of the control circuit 22 is loaded and in resonance, which occurs when the ozone generation circuitry 23 is producing ozone. In one embodiment, the AC current sensor 26 determines that ozone is not being properly produced when the magnitude of the AC current flowing from the control circuit's AC output is less than about 300 mA.

Accordingly, the AC current sensor 26 can be used to indirectly detect ozone production of the ozone generation circuitry 23. Indirectly detecting ozone production avoids a need to manually inspect the operation of the ozone generation circuitry 23 and/or avoids a need to test a treatment fluid for ozone levels. For example, when the electrical system 20 is included in the ozone generator 1 of FIG. 1, the AC current sensor 26 can indirectly detect ozone production in the treatment fluid 15 without needing to test ozone concentrations of the treatment fluid 15.

The control circuit 22 can alert a user of the status of ozone production in a variety of ways. In one embodiment, the control circuit 22 provides at least one of a visual indication, an audio indication, or an electronic notification.

In one example, the control circuit 22 controls a visual indicator, such as a light or display, based on the AC current sensed by the AC current sensor 26. In certain implementations, the visual indicator can be located in the control circuit 22, including, for example, as part of the AC current sensor 26. However, the visual indicator can be in other locations, including, for example, positions visible from outside an ozone generator's housing. Moreover, multiple visual indicators can be provided.

In another example, the control circuit 22 controls an audio indicator, such as a speaker or buzzer, based on the AC current sensed by the AC current sensor 26. In certain implementations, the audio indicator is located in the control circuit 22, including, for example, as part of the AC current sensor 26. However, the audio indicator can be in other locations, including, for example, inside an ozone generator's housing or exterior to the ozone generator's housing. Moreover, multiple audio indicators can be provided.

In yet another example, the control circuit 22 sends an electronic notification based on the AC current sensed by the AC current sensor 26. For example, the control circuit 22 can send an electronic message to a computer or mobile device over a wired or wireless network. For example, the control circuit 22 can include a transceiver chip for wirelessly communicating with electronics external to the ozone generator and/or the control circuit 22 can be coupled to a network via a network cable.

In certain configurations, the control circuit 22 is implemented on a printed circuit board (PCB), such as a laminated PCB. However, the control circuit 22 can be implemented on a wide variety of substrates or boards. The control circuit 22 can include discrete components and/or semiconductor chips arranged to provide electronic monitoring of an ozone generator.

Additional details of the electrical system 20 can be as described earlier.

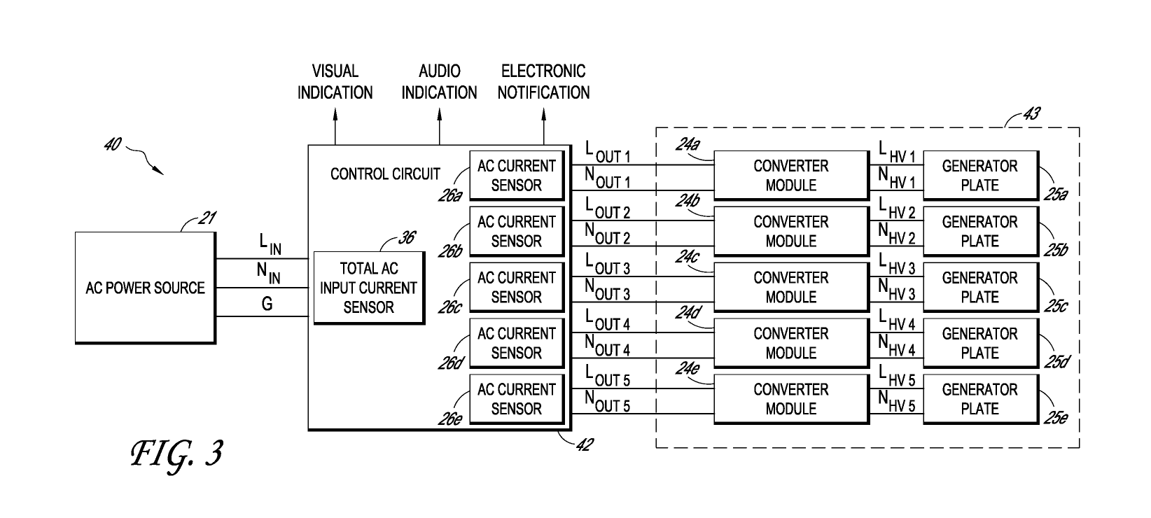

FIG. 3 is a schematic diagram of an electrical system 40 for an ozone generator according to another embodiment. The electrical system 40 includes an AC power source 21, a control circuit 42, and ozone generation circuitry 43.

The illustrated control circuit 42 includes a first AC current sensor 26a, a second AC current sensor 26b, a third AC current sensor 26c, a fourth AC current sensor 26d, a fifth AC current sensor 26e, and a total AC input current sensor 36. As shown in FIG. 3, the ozone generation circuitry 43 includes a first converter module 24a, a second converter module 24b, a third converter module 24c, a fourth converter module 24d, a fifth converter module 24e, a first generator plate 25a, a second generator plate 25b, a third generator plate 25c, a fourth generator plate 25d, and a fifth generator plate 25e.

Although FIG. 3 illustrates a configuration of ozone generation circuitry including five converter modules and five generator plates, other configurations are possible. For example, the ozone generation circuitry can be adapted to include more or fewer converter modules and/or generator plates and/or the ozone generation circuitry can be implemented in other ways. In certain configurations, the generator plates are housed in an ozone generation module, which in turn is housed in an ozone generator.

As shown in FIG. 3, the control circuit 42 receives AC power from the AC power source 21 over L_{IN}, N_{IN}, and G connections. Additionally, the control circuit 42 provides multiple AC output voltages to the ozone generation circuitry 43.

For example, the control circuit 42 includes a first AC output that provides a first AC output voltage to the first converter module 24a using the L_{OUT1} and N_{OUT1} connections. Additionally, the control circuit 42 includes a second AC output that provides a second AC output voltage to the second converter module 24b using the L_{OUT2} and N_{OUT2} connections. Furthermore, the control circuit 42 includes a third AC output that provides a third AC output voltage to the third converter module 24c using the L_{OUT3} and N_{OUT3} connections. Additionally, the control circuit 42 includes a fourth AC output that provides a fourth AC output voltage to the fourth converter module 24d using the L_{OUT4} and N_{OUT4} connections. Furthermore, the control circuit 42 includes a fifth AC output that provides a fifth AC output voltage to the fifth converter module 24e using the L_{OUT5} and N_{OUT5} connections.

The converter modules 24a-24e are used to convert the AC output voltages generated from the control circuit 42 into high voltage AC supplies suitable for generating ozone via the generator plates 25a-25e. The converter modules 24a-24e can convert not only the magnitude of the AC output voltages from the control circuit 42, but also the frequency of the AC output voltages. For example, the converter modules 24a-24e can be used to generate high voltage AC supplies having a frequency suitable for supplying energy into high voltage LC resonant circuits formed by the converter modules and generator plates.

In the illustrated embodiment, the first converter module 24a provides a first high voltage AC supply to the first generator plate 25a using the L_{HV1} and N_{HV1} connections. Additionally, the second converter module 24b provides a second high voltage AC supply to the second generator plate 25b using the L_{HV2} and N_{HV2} connections. Furthermore, the third converter module 24c provides a third high voltage AC supply to the third generator plate 25c using the L_{HV3} and N_{HV3} connections. Additionally, the fourth converter module 24d provides a fourth high voltage AC supply to the fourth generator plate 25d using the L_{HV4} and N_{HV4} connections. Furthermore, the fifth converter module 24e provides a fifth high voltage AC supply to the fifth generator plate 25e using the L_{HV5} and N_{HV5} connections.

Although FIG. 3 illustrates a configuration of a control circuit including five AC current sensors and one total AC current sensor, other configurations are possible.

The first to fifth AC current sensors 26a-26e measure a flow of AC current from the control circuit's first to fifth AC outputs, respectively, to the ozone generation circuitry 43.

Since the high voltage AC supply that powers a particular generator plate is generated by resonance of the generator plate and an associated converter module, the flow of AC current can decrease when the generator plate and converter module are out of resonance. Resonance can be lost for a variety of reasons, including when the control circuit 42 and/or a converter module fail (for example, an open or short circuit), and/or when the AC power supply 21 fails. Moreover, resonance can be lost when a particular generator plate is defective and/or when electrical arcing occurs between one generator plate and another.

Accordingly, the first to fifth AC current sensors 26a-26e are used to measure the AC current flowing through the control circuit's first to fifth AC outputs, respectively. The first to fifth AC current sensors 26a-26e can be used to indirectly detect whether or not the first to fifth generator plates 25a-25e, respectively, are producing ozone. When a particular generator plate is producing ozone, the generator plate can be in resonance with an associated converter module, and the AC current flowing into the converter module can be relatively high. However, when the generator plate is not producing ozone, the generator plate can fall out of resonance with the converter module, and the AC current flowing into the converter module can be relatively low.

Accordingly, the first to fifth AC current sensors 26a-26e indirectly detect whether or not the first to fifth generator plates 25a-25e, respectively, are producing ozone. Indirectly detecting ozone production avoids a need to manually inspect the operation of the ozone generation circuitry 43 and/or avoids a need to test a treatment fluid for ozone levels.

The control circuit 42 can alert a user of the status of ozone production in a variety of ways. In one embodiment, the control circuit 42 provides at least one of a visual indication, an audio indication, or an electronic notification.

Thus a variety of indications and/or notifications can be generated based on the AC currents sensed by the first to fifth AC current sensors 26a-26e. The indications and/or notifications can alert a user as to a particular generator plate that is not producing ozone, thereby helping the user to locate the fault. In one embodiment, each of the first to fifth AC current sensors 26a-26e includes a light, such as a light-emitting diode (LED), that is activated based on whether or not the AC current flowing through the AC current sensor is greater than a current threshold. However, other configurations are possible.

The illustrated control circuit 42 further includes the total AC input current sensor 36, which is used to detect a flow of at least a portion of the AC input current into the control circuit 42 from the AC power source 21. In certain configurations, the total AC input current sensor 36 measures a total of the AC input current that flows from the control circuit's AC input to the control circuit's AC outputs, but excludes AC current used to provide control or monitoring operations. However, other configurations are possible.

When one or more of the converter modules 24a-24e and/or generator plates 25a-25e is not properly functioning, the AC input current to the control circuit 42 can drop. Accordingly, the illustrated total AC input current sensor 36 measures the AC input current flowing into the control circuit 42 to detect when at least one of the generator plates 25a-25e is not producing ozone.

The control circuit 42 can generate a visual indication, an audio indication, and/or an electronic notification based on the AC input current sensed by the AC input current sensor 36. In one embodiment, the control circuit 42 controls a visual indicator, such as a light-emitting diode, that is on an exterior of the ozone generator based on the sensed AC input current. For example, the control circuit 42 can activate the light-emitting diode when the sensed AC current is less than a threshold current, thereby alerting a user that at least one of the generator plates is not producing ozone. In such a configuration, the user can receive the notification without needing to open the ozone generator, since the light is visible from outside the ozone generator's housing. However, other configurations are possible.

Additional details of the electrical system 40 can be as described earlier.

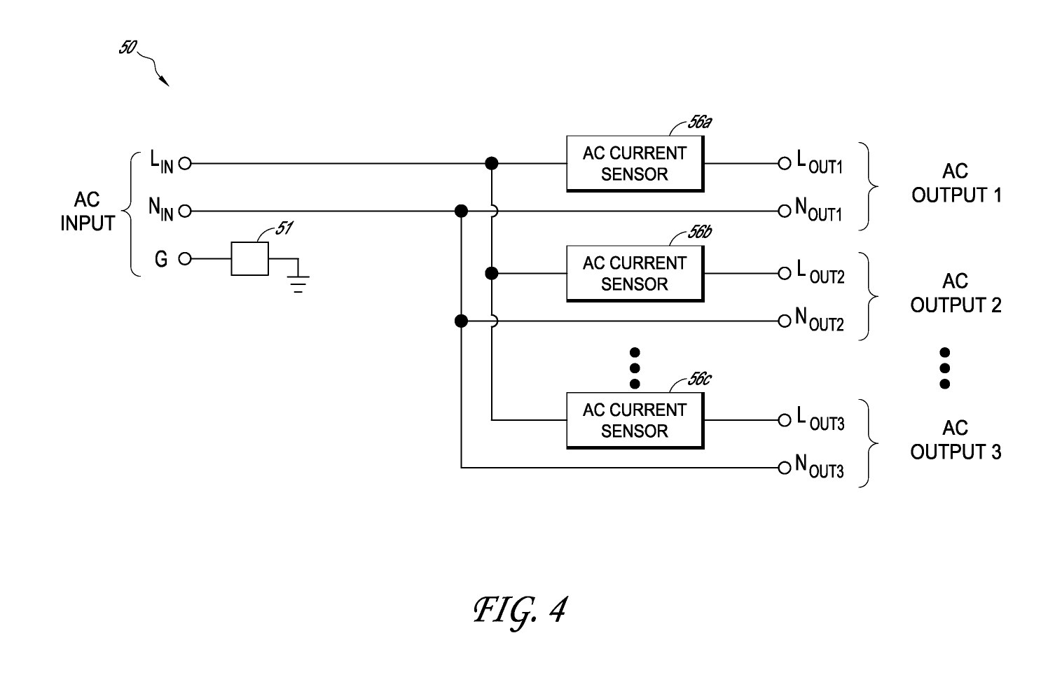

FIG. 4 is a schematic diagram of a control circuit 50 according to one embodiment. The control circuit 50 includes a first AC current sensor 56a, a second AC current sensor 56b, a third AC current sensor 56c, and a grounding circuit 51. The control circuit 50 further includes an AC input including L_{IN}, N_{IN}, and G connections. The control circuit 50 further includes a first AC output including L_{OUT1} and N_{OUT1} connections, a second AC output including L_{OUT2} and N_{OUT2} connections, and a third AC output including L_{OUT3} and N_{OUT3} connections.

Although FIG. 4 illustrates a configuration including three AC outputs and AC current sensors, the control circuit 50 can be adapted to include more or fewer AC outputs and/or AC current sensors.

The control circuit 50 can be implemented in a variety of ways. In certain configurations, the control circuit 50 is implemented as a PCB, and the grounding circuit 51 and AC currents sensors 56a-56c are implemented using components attached to the PCB. However, other configurations are possible, including, for example, configurations in which AC current sensors are not attached to a board.

The grounding circuit 51 is used to electrically connect the G connection of the AC input to ground. The grounding circuit 51 aids in increasing the safety of an ozone generator that includes the control circuit 50.

The first AC current sensor 56a is in an electrical path between the L_{IN} connection of the AC input and the L_{OUT1} connection of the first AC output. The first AC current sensor 56a can detect when the first AC output is loaded and in resonance by ozone generation circuitry, thereby indirectly detecting whether or not ozone is being produced. Additionally, the second AC current sensor 56b is in an electrical path between the L_{IN} connection of the AC input and the L_{OUT2} connection of the second AC output. The second AC current sensor 56b can detect when the second AC output is loaded and in resonance by ozone generation circuitry. Furthermore, the third AC current sensor 56c is in an electrical path between the L_{IN} connection of the AC input and the L_{OUT3} connection of the third AC output. The third AC current sensor 56c can detect when the third AC output is loaded and in resonance by ozone generation circuitry.

Although FIG. 4 illustrates a configuration in which AC current sensors are disposed between line in and line out connections of a control circuit, other implementations are possible.

Additional details of the control circuit 50 can be as described earlier.

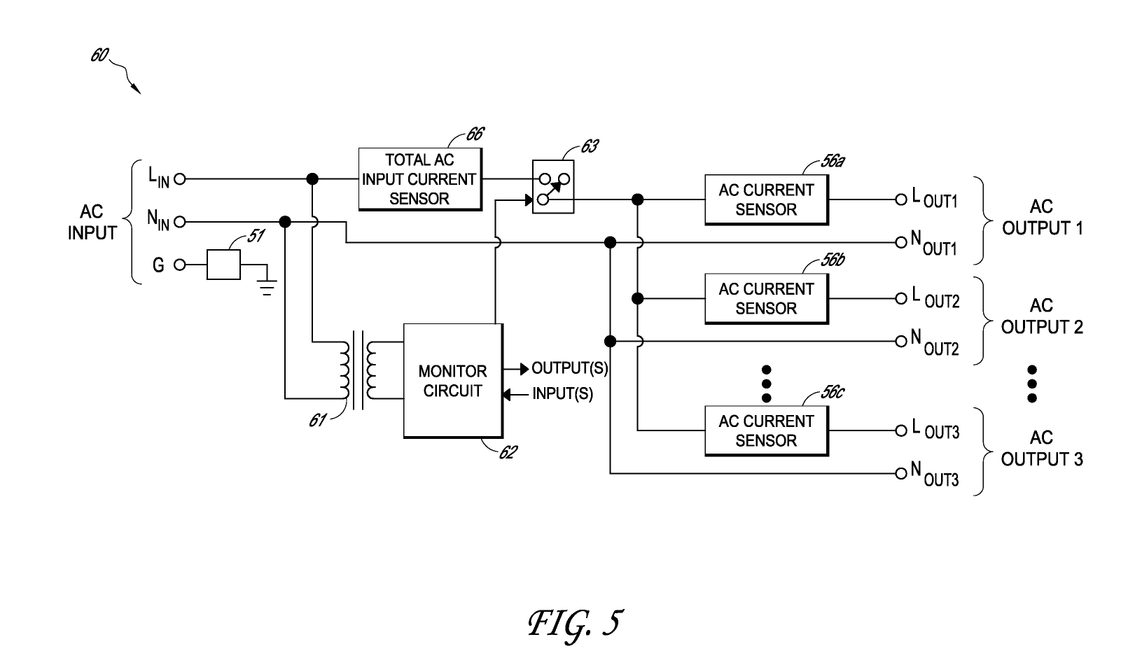

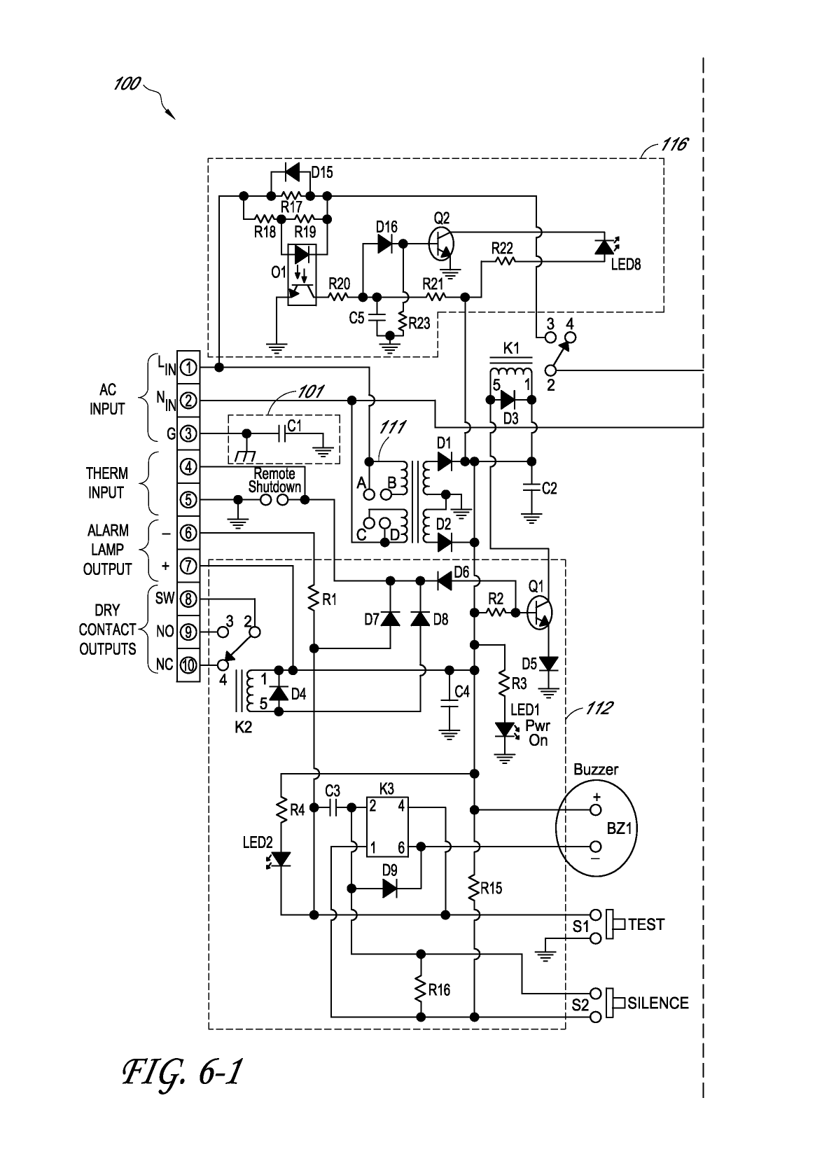

FIG. 5 is a schematic diagram of a control circuit 60 according to another embodiment. The control circuit 60 includes the grounding circuit 51, the first AC current sensor 56a, the second AC current sensor 56b, and the third AC current sensor 56c, which can be as described earlier. The control circuit 60 further includes an AC input, a first AC output, a second AC output, and a third AC output, which can be as described earlier. The control circuit 60 further includes a step down transformer 61, a monitor circuit 62, a switch 63, and a total AC input current sensor 66.

Although FIG. 5 illustrates a configuration including three AC outputs and four AC current sensors, the control circuit can be adapted to include more or fewer AC outputs and/or AC current sensors.

The control circuit 60 of FIG. 5 includes the switch 63, which can be used to turn off ozone production by controlling power to the first, second, and third AC outputs. For example, in the illustrated configuration, the switch 63 can be used to disconnect the L_{IN} connection of the AC input from the first, second, and third AC outputs. As shown in FIG. 5, the monitor circuit 62 controls a state of the switch 63.

The step down transformer 61 is used to generate an AC step-down voltage having a magnitude less than the AC input voltage received on the AC input. For example, in certain implementations, the AC input voltage can be a 120 V supply from a wall outlet, and the step down transformer 61 can be used to generate the AC step-down voltage to have a magnitude less than 120 V, for instance, 10 V or 12 V.

The monitor circuit 62 can receive one or more input signals, including, for example, signals from users, sensors, or other devices, such as a thermostat that monitors the temperature of ozone generation circuitry. The monitor circuit 62 processes the input signals to control the state of the switch 63. Furthermore, in certain implementations, the monitor circuit 62 generates one or more output signals, which can be used, for example, to control visual and/or audio indicators and/or to generate electronic notifications.

Additional details of the control circuit 60 can be as described earlier.

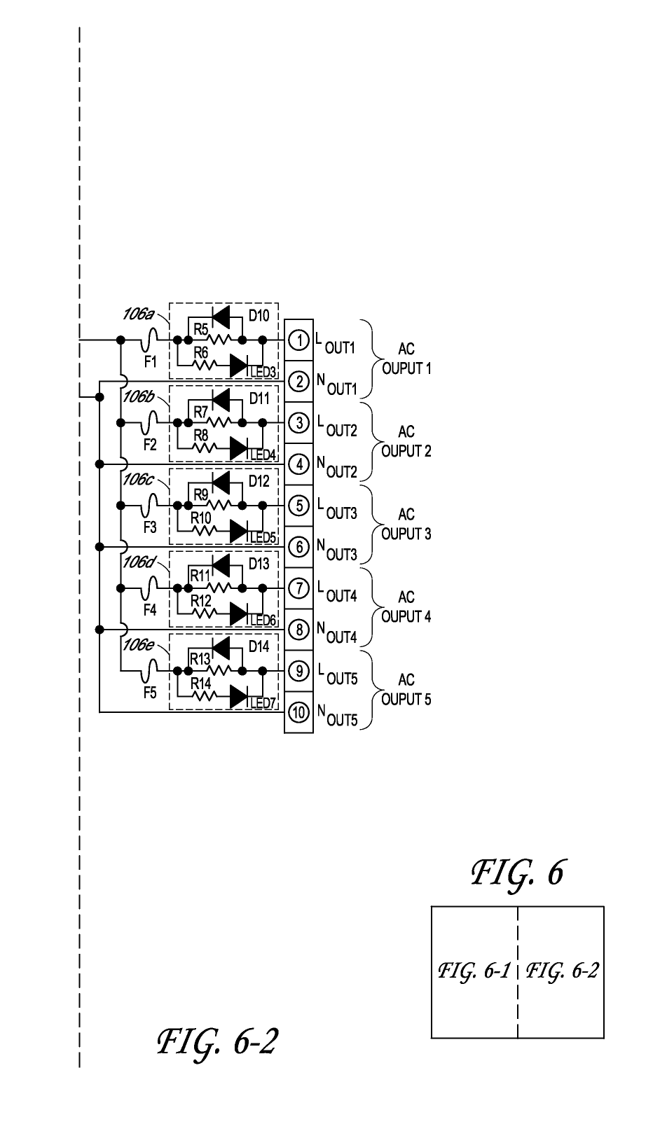

FIG. 6 is a circuit diagram of a control board 100 according to one embodiment. The control board 100 includes a grounding circuit 101, a first AC current sensor 106a, a second AC current sensor 106b, a third AC current sensor 106c, a fourth AC current sensor 106d, a fifth AC current sensor 106e, a step down transformer 111, monitor logic 112, and a total AC input current sensor 116. Various circuit elements have been labeled in FIG. 6, including first to twenty-third resistors R1-R23, first to eighth light-emitting diodes LED1-LED8, first to sixteenth diodes D1-D16, first to third relays K1-K3, first and second bipolar transistors Q1-Q2, buzzer BZ1, first and second input switches S1-S2, first to fifth capacitors C1-C5, first to fifth fuses F1-F5, and opto-isolator O1.

Additionally, various input and output pins of the control board 100 have been illustrated in FIG. 6. The control board 100 includes an AC input including L_{IN}, N_{IN}, and G connections. The control board 100 further includes a thermostat input, which can be provided by a thermostat that monitors a temperature of ozone generation circuitry. The control board 100 further includes an alarm lamp output, which can be coupled to an alarm lamp. The control board 100 further includes dry contact outputs including SW, NO, and NC connections. The control board 100 further includes a first AC output including L_{OUT1} and N_{OUT1} connections, a second AC output including L_{OUT2} and N_{OUT2} connections, a third AC output including L_{OUT3} and N_{OUT3} connections, a fourth AC output including L_{OUT4} and N_{OUT4} connections, and a fifth AC output including L_{OUT5} and N_{OUT5} connections.

As shown in FIG. 6, the grounding circuit 101 is used to electrically connect the G connection of the AC input to chassis ground and to electrically connect the G connection of the AC input to ground via the first capacitor C1. Configuring the grounding circuit 101 in this manner increases safety by grounding the ozone generator's chassis, thereby decreasing a risk that a user touching the ozone generator is shocked when the ozone generator malfunctions (for example, an open circuit or a short circuit).

The illustrated control board further includes the step down transformer 111, which can be used to transform the AC input voltage received at the control board's AC input to an AC step-down voltage suitable for powering the monitor logic 112. In one example, the AC step-down voltage has a magnitude of about 12 V. As shown in FIG. 6, the monitor logic 112 can receive one or more input signals, including, for example, the thermostat input and user inputs from the first and second switches S1, S2. The monitor logic 112 processes the inputs signals to control the first relay K1. The monitor logic 112 can control the first relay K1 to shut off turn off ozone production by controlling power to the control board's AC outputs. For example, in the illustrated configuration, the first relay K1 can be used to selectively disconnect the L_{IN} connection of the AC input from the first, second, third, fourth, and fifth AC outputs.

As shown in FIG. 6, the monitor logic 112 can control a variety of visual and audio indicators. For example, the monitor logic 112 can activate the first light-emitting diode LED1 when power is received from the AC input. Additionally, the monitor logic 112 can activate the buzzer BZ1, the second LED2, and/or an external alarm lamp when a high temperature fault occurs. In the illustrated configuration, the monitor logic 112 can be tested using the first switch S1 or silenced using the second switch S2.

The third relay K3 can be used to set the monitor logic 112 in a fault condition. For example, a voltage between the pins 1 and 2 of the third relay K3 can control the relay's state. In one implementation, the third relay K3 is implemented using part PVG612, available from International Rectifier of El Segundo, Calif.

The illustrated first to fifth AC outputs can be used to provide AC output voltages to ozone generation circuitry, including, for example, power converters and generator plates. Although a control board with five AC outputs is shown, a control board can include more or fewer AC outputs. As shown in FIG. 6, the first AC current sensor 106a is electrically connected in a first electrical path between the AC input and the first AC output. Similarly, the second to fifth AC current sensors 106b-106e are electrically connected in second to fifth electrical paths, respectively, between the AC input and the second to fifth AC outputs.

In the illustrated configuration, each AC current sensor includes a diode, a first resistor, a second resistor, and a light-emitting diode. For example, the first AC current sensor 106a includes the diode D10, the resistor R5, the resistor R6, and the light-emitting diode LED3. During normal operation of an ozone generator, ozone generation circuitry that is connected to the control board's first AC output is producing ozone, and the LED3 is turned on. In particular, in response to an AC current draw on the first AC output that is greater than a certain level, resistor R5 develops a voltage drop sufficient to turn on LED3. Additionally, D10 prevents reverse bias to the light-emitting diode LED3 during an opposite AC half-cycle of the line voltage, and resistor R6 limits the current through the light-emitting diode LED3 to prevent damage. In the illustrated configuration, sensing is on a half-cycle. However, other implementations are possible. The second to fifth AC current sensors 106b-106e can operate in a similar manner.

Although FIG. 6 illustrates one specific implementation of AC current sensors, other implementations are possible. As persons having ordinary skill in the art will appreciate, AC current sensors can be implemented in a wide variety of ways.

The control board's AC outputs can be used to provide AC output voltages to ozone generation circuitry. As was described earlier, the ozone generation circuitry can include high voltage inductor-capacitor (LC) resonant circuits that are powered using the AC output voltages provided by the control board 100. When ozone generation circuitry is properly functioning and producing ozone, a corresponding high voltage LC resonant circuit can be in resonance and draw a relatively large AC current from the control board 100.

However, when the ozone generation circuitry is not producing ozone, such as when a generator plate cracks open or shorts, the high voltage LC resonant circuit can fall out of resonance, and a corresponding AC output of the control board 100 can become unloaded. For example, a resonance of the high voltage LC resonant circuit can be relatively narrow, and a relatively small deviation from the resonance point can cause the AC current drawn from the control board 100 to drop by a relatively large amount. Thus, the AC current sensors 106a-106e can be used to detect ozone production, and can detect faults associated with, for example, defective generator plates, electrical shorts, electrical opens, and/or electrical arcing.

In the illustrated embodiment, the AC current sensors 106a-106e each control a light-emitting diode that is turned on when a corresponding AC output is loaded and in resonance and that turns off when the AC output falls out of resonance. However, other configurations are possible.

The illustrated total AC input current sensor 116 is used to detect when at least one of the control board's AC outputs is unloaded. The AC input current sensor 116 can operate similar to the AC current sensors 106a-106e, except that the AC input current sensor 116 has a higher current threshold for sensing. In one embodiment, a control board includes n AC outputs and n AC output current sensors having a current threshold I_{THRESH}, and a total AC input current sensor is implemented to have a current threshold that is about equal to n*I_{THRESH}.

In comparison to the illustrated AC current sensors 106a-106e, the total AC input current sensor 116 includes a parallel combination of resistor R19 and opto-coupler O1 rather than a light-emitting diode. The opto-coupler O1 is used to turn on the light-emitting diode LED8 when a fault condition occurs. Thus, in contrast to the AC current sensors 106a-106e that turn on a light-emitting diode when a corresponding AC output is loaded, the total AC input current sensor 116 turns on the light-emitting diode LED8 when at least one of the AC outputs is unloaded. However, other configurations are possible.

Although FIG. 6 illustrates one specific embodiment in which AC current sensors alert a user of ozone production using light-emitting diodes, the teachings herein are applicable to control circuits that alert a user to the status of ozone production in a variety ways. For example, AC current sensors can be used to generate a wide variety of visual indications, audio indications, and/or electronic notifications. Additionally, an AC current sensor need not include an indicator such as an LED as part of the sensor. For example, an AC current sensor can include a voltage comparator or other circuitry that drives separate alarm circuitry, including, for instance, circuitry that is on and/or off of a control board.

Additional details of the control board 100 can be as described earlier.

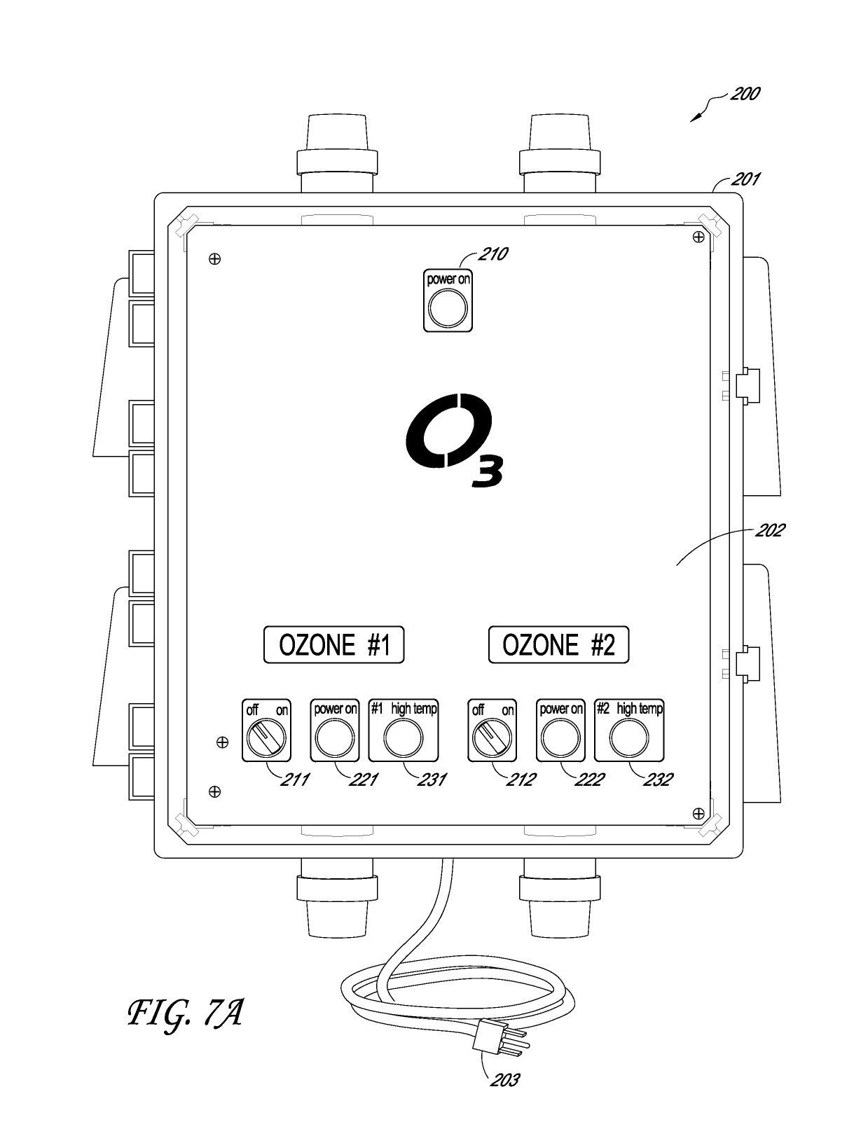

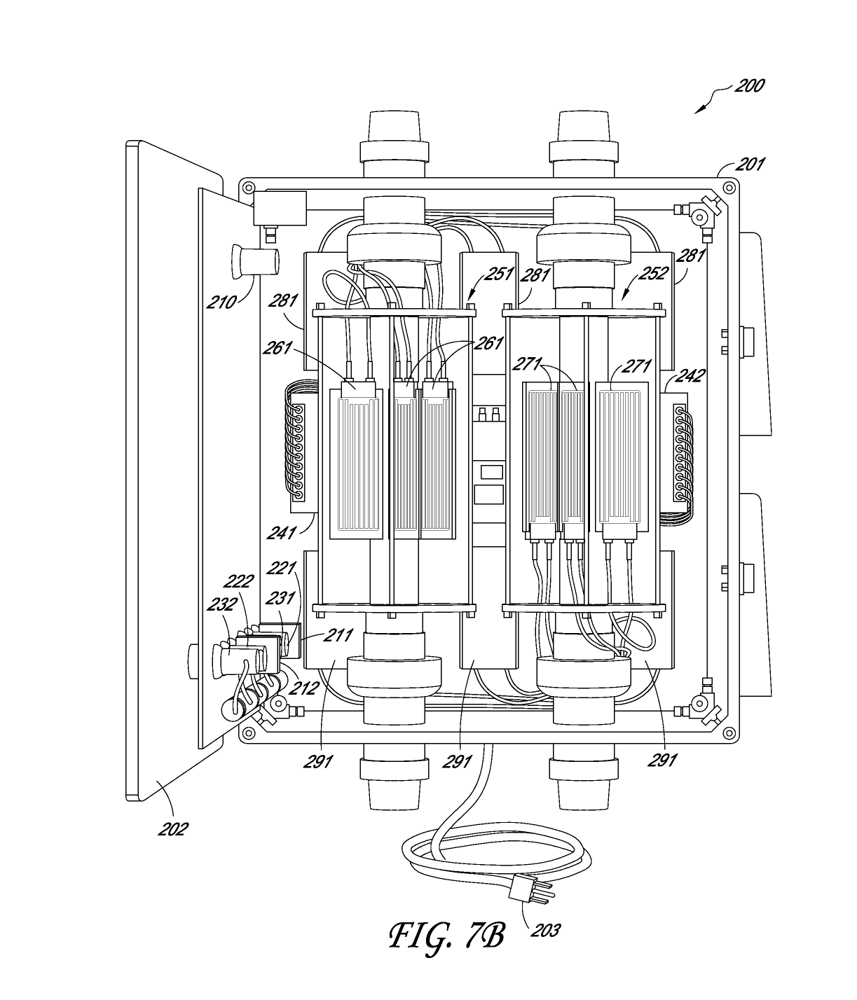

FIG. 7A is a front view of one embodiment of an ozone generator 200 with a front cover 202 closed. FIG. 7B is a front view of the ozone generator 200 of FIG. 7A with the front cover 202 open.

The ozone generator 200 includes a housing 201, a cover 202, a power cord 203, a system power on indicator light 210, a first on/off switch 211, a second on/off switch 212, a first power on indicator light 221, a second power on indicator light 222, a first high temperature warning light 231, a second temperature warning light 232, a first control board 241, a second control board 242, a first ozone generation module 251, a second ozone generation module 252, a first group of power converter modules 281, and a second group of power converter modules 291. The first generation module 251 includes a first group of generator plates 261, and the second ozone generation module 252 includes a second group of generator plates 271.

The ozone generator 200 can be used in a wide variety of applications. For example, the ozone generator 200 can be used to disinfect water and eliminate high biological oxygen demand (BOD). Moreover, the ozone generator 200 can be used to remove odors in many types of waste water, including soluble oil and industrial waste tanks. Furthermore, the ozone generator 200 can be used to destroy various organic chemicals (VOCs) in industrial applications. Additionally, the ozone generator 200 can be used to provide oxidation of hazardous metals for industrial waste water treatment. Furthermore, the ozone generator 200 can be used for treatment of residential septic systems and/or filtration systems.

The ozone generator 200 provides water treatment by generating ozone, which is one of the most effective agents for killing bacteria, destroying odors and VOCs, and oxidizing hazardous and other unwanted metals. For instance, ozone has an oxidation potential that is about 5 times greater than that of chlorine and about 1.5 times greater than that of hydrogen peroxide.

In the illustrated configuration, the ozone generator 200 includes two ozone generation modules 251, 252 that include the first and second groups of generator plates 261, 271, respectively. However, other configurations are possible, including, for example, configurations including more or fewer ozone generation modules.

In certain configurations, the first and second groups of generator plates 261, 271 each include five generator plates arranged in a star or spiral pattern. Additionally, the first and second groups of converter modules 281, 291 each include five power converters used to provide a high voltage AC supply to respective generator plates. However, other configurations are possible, including, for example, configurations using more or fewer generator plates and/or more or fewer converter modules.

The first and second control boards 241, 242 can be used to activate the first and second high temperature warning lights 231, 232, respectively, when the detected temperature of the first and second ozone generation modules 251, 252 is too high. For instance, the first and second control boards 241, 242 can be used to provide high heat shutdown of temperatures of, for instance, 140° C. or more.

The first and second control boards 241, 242 provide monitoring of ozone generation of the first and second ozone generation modules 251, 252, respectively. For example, in the illustrated configuration, the first control board 241 includes AC outputs that provide AC output voltages to the first group of converter modules 281, which in turn provide high voltage AC supplies to the first group of generator plates 261. Thus, the first control board 241 monitors the first ozone generation module 251 and its associated ozone generation circuitry. Additionally, in the illustrated configuration, the second control board 242 includes AC outputs that provide AC output voltages to the second group of converter modules 291, which in turn provide high voltage AC supplies to the second group of generator plates 271. Thus, the second control board 242 monitors the second ozone generation module 252 and its associated ozone generation circuitry.

In the illustrated configuration, a user can control the flow of AC input power to the first and second control boards 241, 242 using the first and second on/off switches 211, 212, respectively. Thus, the ozone generation modules 251, 252 can be individually turned off or on in this embodiment. However, other configurations are possible.

The first control board 241 controls the first power on indicator light 221 and the first high temperature warning light 231, and the second control board 242 controls the second power on indicator light 222 and the second temperature warning light 232. Additionally, each of the first and second control boards 241, 242 include LEDs disposed thereon that indicate whether or not each of the generator plates in the first and second groups of generator plates 261, 271 are producing ozone.

However, the first and second control boards 241, 242 can be configured to alert a user of ozone production in other ways. For example, the control boards 241, 242 can alert a user as to the functioning of the ozone generator 200 in a variety of ways, including, for example, by controlling a visual indicator such as a light, by controlling an audio indicator such as a buzzer, and/or by sending an electronic notification.

In the illustrated configuration, the ozone generation modules 251, 252 are positioned inside the housing 201. In certain configurations, the housing 201 can include a locking and/or latching mechanism to secure the front cover 202 to the housing 201. The housing 201 can include one or more oxygen inlet ports for oxygen/air intake and one/or more ozone outlet ports for providing ozone. In certain implementations, the housing 201 includes one or more wiring ports through which wires or other electrical connections such as the plug 203 can pass to facilitate powering electronics. The housing 201 can also include one or more vents for air flow into and/or out of the housing 201. The housing 201 can be implemented using a variety of materials, including, for example, polycarbonate.

In the illustrated configuration, the ozone generator 200 includes the plug 203, which can be plugged into an AC power source, such as a 120 V outlet. The plug 203 can be coupled to AC inputs of the first and second control boards 241, 242. However, other configurations are possible.

Additional details of the ozone generator 200 can be as described earlier.

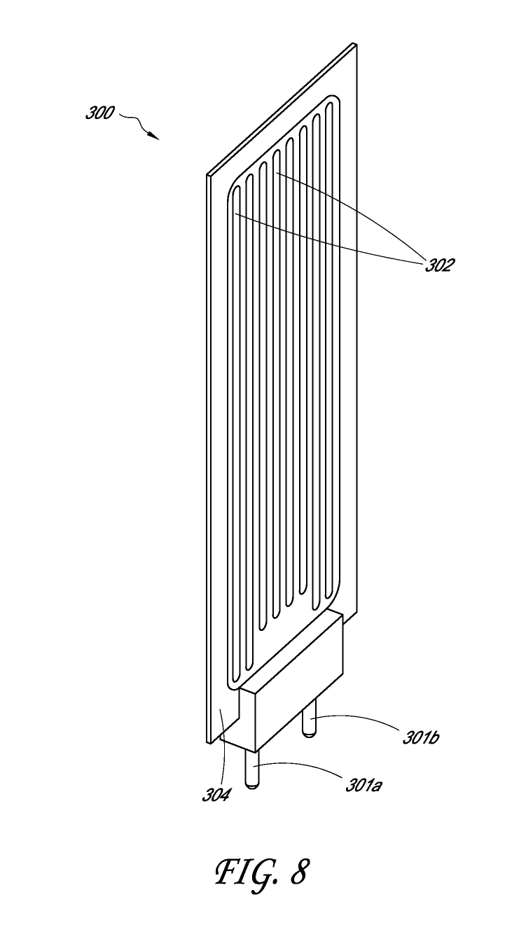

FIG. 8 is a perspective view of one embodiment of a generator plate 300. The generator plate 300 includes a first input connector 301a, a second input connector 301b, a first group of conductive elements 302, a second group of conductive elements (not shown in FIG. 8), and a dielectric body 304.

The first input connector 301a is electrically connected to the first group of conductive elements 302, which are implemented in a finger pattern on a first side of the generator plate 300. Additionally, the second input connector 301b is electrically connected to the second group of conductive elements, which are on a second side of the generator plate 300 that is opposite the first side. In certain implementations, the first and second groups of conductive elements are mirror images of one another. The first and second groups of conductive elements operate as two plates of a capacitor separated by dielectric.

In certain implementations, the first and second groups of conductive elements are implemented using foil. Implementing the first and second groups of conductive elements in foil as finger patters can provide very high electric fields, since such conductive elements are relatively thin and have an extended edge perimeter. Providing very high electric fields can generate corona discharge, which in turn produces ozone.

When the generator plate 300 is in resonance with a converter module, the voltage between the first and second input connectors 301a, 301b is a high voltage AC supply. For instance, when the generator plate 300 is included in the electrical system 20 of FIG. 3, the first and second input connectors 301a, 301b can be electrically connected to the L_{HV} and N_{HV} connections, respectively. When the generator plate 300 is in resonance, both sides of the generator plate 300 generate corona discharge that produces ozone.

The dielectric body 304 can be implemented using a wide variety of materials. In certain implementations, the dielectric body 304 is implemented using a ceramic.

The generator plate 300 illustrates one example of a generator plate that can be used in the ozone generators described herein. However, ozone generators can be configured to operate with other implementations of generator plates.

### CONCLUSION

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. An ozone generator comprising:
ozone generation circuitry; and
a control circuit comprising an AC input configured to receive an AC input voltage and one or more AC outputs configured to provide one or more AC output voltages to the ozone generation circuitry,
wherein the control circuit further comprises a first AC current sensor configured to sense an AC current flowing from a first AC output of the one or more AC outputs into the ozone generation circuitry.

2. The ozone generator of claim 1, wherein the ozone generation circuitry comprises a first generator plate, wherein the first AC current sensor is configured to detect when the first generator plate is producing ozone.

3. The ozone generator of claim 1, wherein the control circuit is configured to generate at least one a visual indication, an audio indication, or an electronic notification based on the sensed AC current.

4. The ozone generator of claim 1, wherein the control circuit further comprises a second AC current sensor configured to sense an AC current flowing from a second AC output of the one or more AC outputs into the ozone generation circuitry.

5. The ozone generator of claim 1, wherein the control circuit further comprises a total AC input current sensor configured to sense an AC input current flowing from the AC input to the one or more AC outputs.

6. The ozone generator of claim 5, wherein the control circuit further comprises a total AC input current sensor configured to sense an AC input current flowing from the AC input to the one or more AC outputs.

7. The ozone generator of claim 1, wherein the control circuit is implemented on a printed circuit board (PCB).

8. The ozone generator of claim 1, wherein the ozone generation circuitry comprises a first inductor-capacitor (LC) resonant circuit, wherein the first AC current sensor is configured to detect when the first LC resonant circuit is in resonance.

9. The ozone generator of claim 1, wherein the first AC current sensor comprises a light that is selectively activated based on the sensed AC current.

10. The ozone generator of claim 1, wherein the ozone generation circuitry comprises one or more converter modules and one or more generator plates, wherein the one or more converter modules include one or more inputs that receive the one or more AC output voltages from the control circuit and one or more outputs that are electrically connected to the one or more generator plates.

11. The ozone generator of claim 1, wherein the control circuit comprises a switch in an electrical path between the AC input and the one or more AC outputs, wherein the control circuit further comprises a monitor circuit that controls a state of the switch based on the one or more input signals.

12. The ozone generator of claim 11, wherein the one or more input signals includes a thermostat signal, wherein the monitor circuit is further configured to disconnect the AC input from the one or more AC outputs using the switch when the thermostat signal indicates a temperature fault condition.

13. A method of electronic monitoring in an ozone generator, the method comprising:
receiving an AC input voltage as an input to a control circuit of an ozone generator;
providing one or more AC output voltages from one or more AC outputs of the control circuit to ozone generation circuitry of the ozone generator; and
detecting when the ozone generation circuitry is producing ozone by sensing one or more AC currents flowing from the one or more AC outputs using one or more AC current sensors.

14. The method of claim 13, further comprising generating at least one a visual indication, an audio indication, or an electronic notification based on the one or more sensed AC currents.

15. The method of claim 13, wherein the ozone generation circuitry comprises one or more inductor-capacitor (LC) resonant circuits, wherein detecting when the ozone generation circuitry is producing ozone further comprises determining when the one or more LC resonant circuits are resonating using the one or more AC current sensors.

16. An apparatus comprising:
a control circuit comprising an AC input, a first AC output, and a first AC current sensor in an electrical path between the AC input and the first AC output;
a first generator plate; and
a first converter module in an electrical path between the first AC output of the control circuit and the first generator plate,
wherein the first AC current sensor is configured to detect when the first converter module and the first generator plate are in resonance.

17. The apparatus of claim 16, wherein an inductance of the first converter module is configured to resonate with a capacitance of the generator plate.

18. The apparatus of claim 17, wherein the first converter module comprises a transformer, wherein the inductance of the first converter module comprises a self-inductance of the transformer.

19. The apparatus of claim 16,
wherein the control circuit further comprises a second AC output and a second AC current sensor in an electrical path between the AC input and the second AC output,
wherein the ozone generator further comprises a second generator plate and a second converter module in an electrical path between the second AC output of the control circuit and the second generator plate,
wherein the second AC current sensor is configured to detect when the second converter module and the second generator plate are in resonance.

20. The apparatus of claim 16, wherein the control circuit is configured to generate at least one a visual indication, an audio indication, or an electronic notification based on the sensed AC current.
